(19) United States
(12) Patent Application Publication
(10) Pub. No.: US 2026/0162705 A1
(43) Pub. Date: Jun. 11, 2026

(54) MEMORY DEVICE, MEMORY CONTROLLER AND MEMORY SYSTEM

(71) Applicant: SAMSUNG ELECTRONICS CO., LTD., Suwon-si (KR)

(72) Inventors: Chinam KIM, Suwon-si (KR); Kwangsu KIM, Suwon-si (KR); Do-Han KIM, Suwon-si (KR); SuJin KIM, Suwon-si (KR); Changmin LEE, Suwon-si (KR)

(73) Assignee: SAMSUNG ELECTRONICS CO., LTD., Suwon-si (KR)

(21) Appl. No.: 19/341,907

(22) Filed: Sep. 26, 2025

(30) Foreign Application Priority Data
Oct. 22, 2024 (KR) 10-2024-0144594
Mar. 20, 2025 (KR) 10-2025-0036143

(51) Int. Cl. G11C 11/406; G11C 11/4096

(52) U.S. Cl. CPC G11C 11/40615; G11C 11/40618; G11C 11/4096

(57) ABSTRACT

A memory system includes a memory device having a plurality of banks, each bank including a plurality of sub-banks, and a memory controller that accesses rows in the banks using either an activate-refresh command or an activate command. The memory device manages a number of hidden refresh operations performed for each sub-bank in response to the activate-refresh command and generates over-refresh state information based on the number of hidden refresh operations. The memory controller transmits the activate-refresh command or the activate command to the memory device according to the over-refresh state information.

### CROSS-REFERENCE TO RELATED APPLICATION(S)

This U.S. non-provisional application claims priority under 35 U.S.C. § 119 to Korean Patent Application Nos. 10-2024-0144594, filed on Oct. 22, 2024 and 10-2025-0036143, filed on Mar. 20, 2025, with the Korean Intellectual Property Office, the disclosures of which are incorporated herein by reference in their entirety.

### BACKGROUND

The present disclosure relates to a memory system, and more particularly, to a memory device, a memory controller, and a memory system that perform effective refresh operations.

Semiconductor memory devices storing data may be classified into volatile memory devices and non-volatile memory devices. Volatile memory devices lose their stored data when their power supplies are interrupted.

In a nonvolatile memory device such as a dynamic random access memory (DRAM) device, cell charges stored in memory cells may be lost due to leakage current. Before the cell charges are lost and data is completely corrupted, the charges in the memory cell should be recharged. Such recharging of the cell charges is referred to as a refresh operation. The refresh operation may be repeatedly performed before the cell charges are lost.

### SUMMARY

The present disclosure provides a memory device, a memory controller, and a memory system that are configured to optimize performance and power consumption by preventing unnecessary hidden refresh operations.

According to an embodiment, a memory system includes a memory device including a plurality of banks, each including a plurality of sub-banks, and a memory controller configured to access a row included in the plurality of banks using an activate-refresh command or an activate command. The memory device may be configured to manage a number of hidden refresh operations, performed based on the activate-refresh command, for each sub-bank and generate over-refresh state information based on the number of hidden refresh operations for each sub-bank, and the memory controller may be configured to selectively transmit the activate-refresh command or the activate command to the memory device based on the over-refresh state information.

A first bank, among the plurality of banks, may include a first sub-bank including a first row and a second sub-bank including a second row. The memory device may be configured to perform an activation operation on the first row and the hidden refresh operation on the second row based on the activate-refresh command for accessing the first row and perform the activation operation on the first row without performing the hidden refresh operation, based on the activate command for accessing the first row.

The over-refresh state information may include a first value corresponding to a state in which the number of hidden refresh operations is less than a threshold and a second value corresponding to a state in which the number of hidden refresh operations is greater than or equal to the threshold. The memory controller may be configured to transmit the activate-refresh command to access the first row based on the over-refresh state information of the second sub-bank being the first value and transmit the activate command to access the first row based on the over-refresh state information of the second sub-bank being the second value.

The over-refresh state information may indicate whether the number of hidden refresh operations performed on a corresponding sub-bank is greater than or equal to a threshold. The memory device may be configured to increase the number of hidden refresh operations on the corresponding sub-bank each time the hidden refresh operation is performed on the corresponding sub-bank during a unit interval and transmit the over-refresh state information corresponding to a time point, at which a first command for inquiring the over-refresh state information is received from the memory controller, to the memory controller.

The unit interval may correspond to a predetermined number of refresh interval times, and the threshold may be determined based on a number of normal refresh commands corresponding to the unit interval and a number of rows refreshed per normal refresh command.

The memory device may be configured to generate count information on a number of skippable normal refresh commands based on the number of hidden refresh operations performed during the unit interval. The memory controller may be configured to transmit a second command for inquiring the count information to the memory device at an end of the unit interval and determine a number of normal refresh commands to be transmitted during a next unit interval based on the count information received from the memory device in response to the second command.

The number of hidden refresh operations may be reduced based on the count information at the end of the unit interval and rolled over to the next unit interval.

The memory controller may be configured to transmit the first command to the memory device a predetermined time before the end of the unit interval.

The memory device may include a plurality of first mode registers configured to store the over-refresh state information of the plurality of sub-banks included in the plurality of banks, and the first command may include a mode register read command for inquiring information stored in the plurality of first mode registers.

The mode register read command may include an update-inquire operation bit. The memory device may be configured to transmit the over-refresh state information stored in the plurality of first mode registers to the memory controller when the update-inquire operation bit has a first value and update the plurality of first mode registers with current over-refresh state information and transmit the updated over-refresh state information to the memory controller when the update-inquire operation bit has a second value.

The mode register read command may include a burst operation bit. The memory device may be configured to transmit the over-refresh state information stored in a first mode register corresponding to an address provided through the mode register read command, among the plurality of first mode registers, to the memory controller when the burst operation bit has a first value and transmit the over-refresh state information stored in the plurality of first mode registers to the memory controller in a batch when the burst operation bit has a second value.

The first command may include a read command. The memory device may include a data I/O buffer including a normal data region and a metadata region, and may be configured to transmit the over-refresh state information of a sub-bank comprising a row corresponding to the read command to the memory controller through the metadata region of the data I/O buffer.

Each of the plurality of banks may include a first sub-bank and a second sub-bank. The first sub-bank and the second sub-bank may be respectively connected to additional row decoders, and may share a column decoder.

According to an embodiment, a memory device includes a plurality of banks, each including a plurality of sub-banks, a control logic circuit configured to activate a row included in the plurality of banks based on an activate-refresh command or an activate command, and a hidden refresh tracking circuit configured to manage a number of hidden refresh operations, performed based on the activate-refresh command, for each sub-bank and generate over-refresh state information, indicating whether the number of hidden refresh operations is greater than or equal to a threshold, for each sub-bank.

The hidden refresh tracking circuit may be configured to increase the number of hidden refresh operations on a corresponding sub-bank each time the hidden refresh operation is performed on the corresponding sub-bank during a unit interval, generate count information on a number of skippable normal refresh commands based on the number of hidden refresh operations performed during the unit interval, and reduce the number of hidden refresh operations on the corresponding sub-bank based on the count information at an end of the unit interval. The unit interval may be a period during which a command for inquiring the count information is received by the memory device.

The memory device may include a plurality of first mode registers configured to store the over-refresh state information of the plurality of sub-banks included in the plurality of banks. The hidden refresh tracking circuit may be configured to update the over-refresh state information in the plurality of first mode registers based on a mode register read command for inquiring information stored in the plurality of first mode registers or an expiration signal of an internal timer.

The mode register read command may include an update-inquire operation bit, and the hidden refresh tracking circuit may be configured to update the plurality of first mode registers with current over-refresh state information when the update-inquire operation bit has an enable value.

The mode register read command may include a burst operation bit, the over-refresh state information stored in one of the plurality of first mode registers may be transmitted to a data input/output buffer when the burst operation bit has a disable value, and over-refresh state information stored in the plurality of first mode registers may be transmitted to the data input/output buffer in a batch when the burst operation bit has an enable value.

The memory device may include a data input/output buffer including a normal data area and a metadata area. The hidden refresh tracking circuit may be configured to transmit the over-refresh state information of a sub-bank including a row corresponding to a read command to the metadata area of the data input/output buffer.

According to an embodiment, a memory controller controlling an operation of a memory device includes a plurality of bank schedulers, respectively corresponding to a plurality of banks included in the memory device. Each of the plurality of bank schedulers may be configured to schedule selective transmission of an activate-refresh command or an activate command to access a row included in a corresponding bank based on over-refresh state information of each of a plurality of sub-banks included in the corresponding bank. The over-refresh state information may indicate whether a number of hidden refresh operations performed on a corresponding sub-bank based on the activate-refresh command is greater than or equal to a threshold, and may be received from the memory device.

### BRIEF DESCRIPTION OF DRAWINGS

FIG. 1 is a block diagram of a memory system according to one or more embodiments.

FIG. 2 is a diagram illustrating a hidden refresh operation according to one or more embodiments.

FIG. 3 is a diagram illustrating the operation of a memory system according to one or more embodiments.

FIG. 4 is a diagram illustrating the operation of a memory system according to one or more embodiments.

FIG. 5 is a diagram for explaining the operation of a memory system according to one or more embodiments.

FIG. 6 is a flowchart illustrating a method of operating a memory device according to one or more embodiments.

FIG. 7 is a flowchart illustrating a method of operating a memory controller according to one or more embodiments.

FIG. 8 is a block diagram of a memory device according to one or more embodiments.

FIG. 9 is a diagram illustrating a plurality of first mode registers according to one or more embodiments.

FIG. 10 is a diagram illustrating a burst operation according to one or more embodiments.

FIG. 11 is a block diagram of a memory controller according to one or more embodiments.

FIG. 12 is a flowchart illustrating the operation of a memory device according to one or more embodiments.

FIG. 13 is a flowchart illustrating the operation of a memory device according to one or more embodiments.

FIG. 14 is a flowchart illustrating the operation of a bank scheduler according to one or more embodiments.

FIG. 15 is a flowchart illustrating a count information inquiring operation of a refresh scheduler according to one or more embodiments.

FIG. 16 is a flowchart illustrating an over-refresh state information inquiring operation of a refresh scheduler according to one or more embodiments.

FIG. 17 is a flowchart illustrating a method of operating a bank scheduler according to one or more embodiments.

### DETAILED DESCRIPTION

The following description with reference to the accompanying drawings is provided to assist in a comprehensive understanding of various embodiments of the present disclosure.

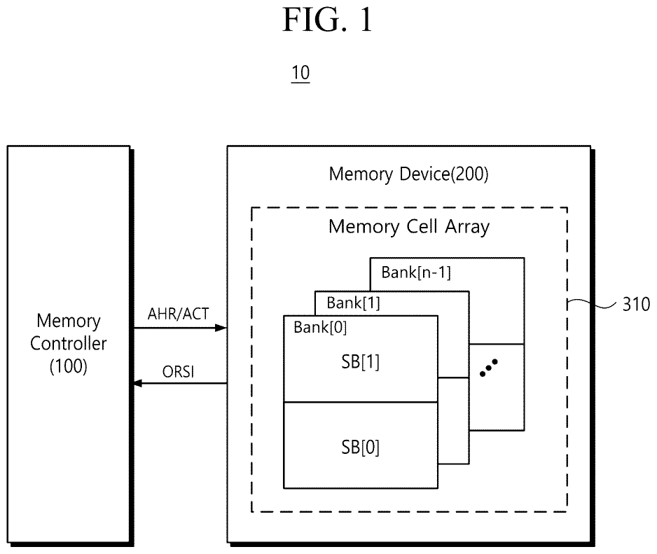

FIG. 1 is a block diagram of a memory system according to one or more embodiments.

A memory system 10 according to one or more embodiments may support a normal refresh operation. For example, the memory controller 100 may periodically transmit a refresh command to the memory device 200, and the memory device 200 may perform a refresh operation based on the refresh command received from the memory controller 100. The refresh command periodically transmitted by the memory controller 100 may be referred to as a normal refresh command. In addition, the refresh operation performed by the memory device 200 in response to the normal refresh command may be referred to as a normal refresh operation. In some cases, the normal refresh command and the normal refresh operation may also be referred to as a regular refresh command and a regular refresh operation, respectively.

The memory system 10 according to one or more embodiments may support a hidden refresh operation. The hidden refresh operation may refer to a refresh operation performed along with another operation based on a predetermined command other than a normal refresh command. For example, the memory system 10 may use an activate-refresh command to access a row included in a bank of the memory device 200. The memory device 200 may perform an activation operation on one row in a bank and a refresh operation on another row based on the activate-refresh command. The refresh operation performed along with the activation operation may be an example of a hidden refresh operation. For clarity, an example is provided in which the hidden refresh operation is a refresh operation performed based on an activate-refresh command.

An access to the bank is not allowed during a normal refresh operation performed in response to a normal refresh command. However, a hidden refresh operation is performed along with an activation operation. Therefore, at least a portion of the normal refresh operations may be replaced with the hidden refresh operation to improve the performance of the memory system 10.

The memory system 10 according to one or more embodiments may use not only an activate-refresh command but also an activate command to access a row included in a bank of the memory device 200. The memory device 200 may perform an activation operation on a single row in the bank without a refresh operation based on the activate command.

The hidden refresh operation is performed along with an activation operation, so that an additional timing delay may be required. This is because a plurality of rows within a single bank are activated during a hidden refresh operation, which increases power noise. Accordingly, unnecessary hidden refresh operations should be avoided.

To this end, the memory system 10 according to one or more embodiments may selectively use an activate-refresh command or an activate command based on over-refresh state information ORSI. The over-refresh state information ORSI may indicate whether the number of hidden refresh operations exceeds a threshold.

For example, the memory system 10 may access a row of a sub-bank using an activate command instead of an activate-refresh command when the number of hidden refresh operations performed on the sub-bank exceeds a threshold. Accordingly, performance degradation or increased power consumption of the memory system 10 caused by unnecessary hidden refresh operations may be prevented.

The activate-refresh command may be referred to as an activate with hidden refresh (AHR) command, and the activate command may be referred to as an ACT command. Hereinafter, for clarity, the activate-refresh command will be referred to as an AHR command and the activate command as an ACT command.

A more detailed description is provided with reference to FIG. 1. The memory system 10 may include a memory controller (MC) 100 and a memory device (MD) 200.

The memory controller (MC) 100 may control the memory device (MD) 200. For example, the memory controller (MC) 100 may control the memory device (MD) 200 based on requests from a processor supporting various applications such as server applications, personal computer (PC) applications, or mobile applications. For example, the memory controller (MC) 100 may be included in a host including a processor and may control the memory device (MD) 200 based on the requests from the processor. For example, the memory controller (MC) 100 may be implemented as a system-on-chip (SoC).

The memory controller 100 may transmit commands and/or addresses to the memory device 200 to control the memory device 200. According to one or more embodiments, an address may be transmitted to the memory device 200 separately from the command or included in the command. For example, the memory controller 100 may transmit commands, such as an AHR command, ACT command, write command, read command, precharge command, or mode register read command, to the memory device 200.

According to one or more embodiments, the memory controller 100 may use an AHR command or an ACT command to access rows included in a plurality of banks Bank [0] to Bank [n-1] of the memory device 200. The memory controller 100 may selectively transmit an AHR command or an ACT command to the memory device 200 based on over-refresh state information obtained from the memory device 200.

The memory device 200 may receive data from the memory controller 100 and store the received data. The memory device 200 may read the stored data in response to a request from the memory controller 100 and transmit the read data to the memory controller 100.

According to one or more embodiments, the memory device 200 may be a memory device including volatile memory cells. For example, the memory device 200 may be one of various DRAM devices such as a double data rate synchronous dynamic random access memory (DDR SDRAM) device, a DDR2 SDRAM device, a DDR3 SDRAM device, a DDR4 SDRAM device, a DDR5 SDRAM device, a DDR6 SDRAM device, a low power double data rate (LPDDR) SDRAM device, an LPDDR2 SDRAM device, an LPDDR3 SDRAM device, an LPDDR4 SDRAM device, an LPDDR4X SDRAM device, an LPDDR5 SDRAM device, a graphics double data rate synchronous graphics random access memory (GDDR SGRAM) device, a GDDR2 SGRAM device, a GDDR3 SGRAM device, a GDDR4 SGRAM device, a GDDR5 SGRAM device, or a GDDR6 SGRAM device.

According to one or more embodiments, the memory device 200 may be a stacked memory device in which DRAM dies are stacked, such as a high bandwidth memory (HBM) device, an HBM2 device, or an HBM3 device.

According to one or more embodiments, the memory device 200 may be a memory module such as a dual in-line memory module (DIMM). For example, the memory module 100A may be a registered DIMM (RDIMM), a load reduced DIMM (LRDIMM), an unbuffered DIMM (UDIMM), a fully buffered DIMM (FB-DIMM), a small outline DIMM (SO-DIMM). However, this is only an example, and the memory device 200 may be another memory module such as a single in-line memory module (SIMM).

According to an embodiment, the memory device 200 may be an SRAM device, a NAND flash memory device, a NOR flash memory device, an RRAM device, an FRAM device, a PRAM device, a TRAM device, or an MRAM device.

The memory device 200 may include a memory cell array 310. The memory cell array 310 may include a plurality of banks Bank[0] to Bank[n-1], and each bank may include memory cells for storing data. For clarity, an example is provided in which each bank includes DRAM cells. However, this is exemplary, and each of the plurality of banks may be implemented to include volatile memory cells other than DRAM cells. In addition, each of the plurality of banks may be implemented to include the same type of memory cells or different types of memory cells.

According to an embodiment, each of the plurality of banks may include a metadata area in which metadata is stored. The metadata area may refer to an area allocated to store metadata, among areas of the bank. The metadata may be data used for purposes other than user data, such as improving the performance or enhancing the security of the memory device 200.

According to one or more embodiments, each of the plurality of banks Bank[0] to Bank[n-1] may include a plurality of sub-banks SB[0] and SB[1]. The plurality of sub-banks SB[0] and SB[1] may be connected to additional row decoders, respectively, and may share a column decoder. FIG. 1 illustrates an example in which one bank includes two sub-banks, but embodiments are not limited thereto and each bank may include three or more sub-banks.

When an AHR command is received from the memory controller 100, the memory device 200 may perform a hidden refresh operation. The memory device 200 may count or manage the number of hidden refresh operations for each sub-bank.

In addition, the memory device 200 may generate over-refresh state information for each sub-bank based on the number of hidden refresh operations. The over-refresh state information may indicate whether the number of hidden refresh operations performed on a corresponding sub-bank exceeds a threshold. The threshold is a predetermined value based on the number of rows refreshed in response to a normal refresh command, and will be described in detail later.

According to one or more embodiments, the over-refresh state information may be represented as a single bit. The single may have a first value (for example, “0”) indicating that the number of hidden refresh operations performed on a corresponding sub-bank is less than the threshold or a second value (for example, “1”) indicating that the number of hidden refresh operations is greater than or equal to the threshold. However, embodiments are not limited thereto, and the over-refresh state information may be represented as two or more bits. The over-refresh state information may include additional information besides whether the number of hidden refresh operations is greater than or equal to the threshold.

The memory device 200 may provide over-refresh state information to the memory controller 100 in response to a command for inquiring the over-refresh state information.

According to one or more embodiments, the memory device 200 may store the over-refresh state information in a mode register. The memory controller 100 may inquire the over-refresh state information from the memory device 200 using a mode register read command and obtain the over-refresh state information from the memory device 200. Hereinafter, the mode register storing the over-refresh state information is referred to as a “first mode register,” and the mode register command for inquiring or polling the over-refresh state information stored in the first mode register is referred to as a “first mode register read command.”

Alternatively, according to one or more embodiments, the memory device 200 may provide the over-refresh state information to the memory controller 100 in the form of metadata. The memory controller 100 may inquire the over-refresh state information from the memory device 200 using a read command and obtain the over-refresh state information from the memory device 200.

The memory controller 100 may selectively transmit an AHR command or an ACT command to the memory device 200 based on the obtained over-refresh state information. For example, when the number of hidden refresh operations performed on a sub-bank is less than the threshold, the memory controller 100 may access a row in the sub-bank using an activate-refresh command. In addition, when the number of hidden refresh operations performed on a sub-bank is greater than or equal to the threshold, the memory controller 100 may access a row in the sub-bank using an activate command rather than an activate-refresh command.

According to the above-described embodiments, unnecessary hidden refresh operations of the memory device 200 may be prevented. Accordingly, the performance and power consumption of the memory device 200 may be improved and reduced.

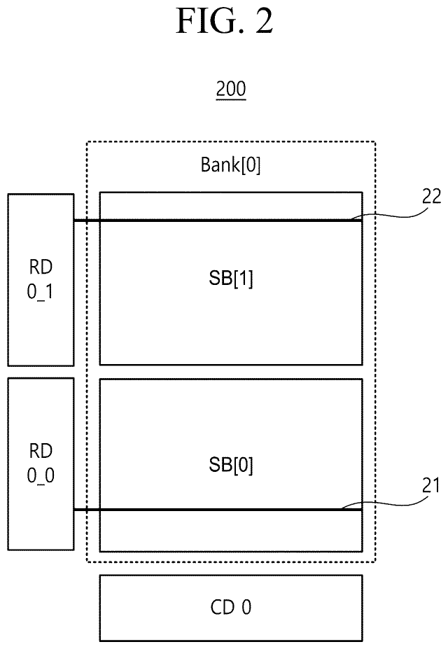

FIG. 2 is a diagram illustrating the operation of the memory system 10 according to one or more embodiments. FIG. 2 illustrates a first bank Bank[0] among the plurality of banks Bank[0] to Bank[n-1] included in the memory device 200, row decoders RD0_0 and RD0_1 corresponding to the first bank Bank[0], and a column decoder CD0.

Referring to FIG. 2, the first bank Bank[0] may include a first sub-bank SB[0] and a second sub-bank SB[1]. The first sub-bank SB[0] may be connected to a first row decoder RD0_0, and the second sub-bank SB[1] may be connected to a second row decoder RD0_1, separate from the first row decoder RD0_0. In addition, the first sub-bank SB[0] and the second sub-bank SB[1] may share a column decoder CD0. Although FIG. 2 illustrates the configuration related to the first bank Bank[0], the remaining banks Bank[1] to Bank[n-1] may have a structure similar to that illustrated in FIG. 2.

The first sub-bank SB[0] and the second sub-bank SB[1] are connected to separate row decoders RD0_0 and RD0_1, so that a first row 21 included in the first sub-bank SB[0] and a second row 22 included in the second sub-bank SB[1] may be activated simultaneously.

Therefore, according to one or more embodiments, when an AHR command is received to access a row included in one of the two sub-banks SB[0], SB[1] of the first bank Bank[0], the memory device 200 may perform an activation operation on the requested row and a hidden refresh operation on a row included in the other sub-bank based on the received AHR command.

For example, when an AHR command is received to access the first row 21, the memory device 200 may perform an activation operation on the first row 21 and a hidden refresh operation on the second row 22 simultaneously. Similarly, when an AHR command is received to access the second row 22, the memory device 200 may perform an activation operation on the second row 22 and a hidden refresh operation on the first row 21 simultaneously.

A row on which the activation operation is performed may correspond to an address included in the AHR command. In addition, a row on which the hidden refresh operation is performed may be one row selected by the memory device 200, among the rows included in the remaining sub-banks that do not include the row on which the activation operation is performed.

When an ACT command is received to access a row included in one of the two sub-banks SB[0] and SB[1] of the first bank Bank[0], the memory device 200 may perform an activation operation on a corresponding row based on the received ACT command. For example, when an ACT command is received, the memory device 200 may perform only the activation operation on the corresponding row without a hidden refresh operation.

According to one or more embodiments, the memory device 200 may manage the number of hidden refresh operations performed based on the AHR command for each sub-bank and generate over-refresh state information for each sub-bank based on the number of hidden refresh operations.

For example, the memory device 200 may count and manage the number of hidden refresh operations performed on the first sub-bank SB[0] and the number of hidden refresh operations performed on the second sub-bank SB[1]. In addition, the memory device 200 may generate over-refresh state information for the first sub-bank SB[0] based on the number of hidden refresh operations performed on the first sub-bank SB[0] and generate over-refresh state information for the second sub-bank SB[1] based on the number of hidden refresh operations performed on the second sub-bank SB[1]. This may be similarly applied to the first and second sub-banks SB[0] and SB[1] included in each of the remaining banks Bank[1] to Bank[n-1].

The memory controller 100 may obtain over-refresh state information from the memory device 200 using a command for inquiring the over-refresh state information. Accordingly, for example, the memory controller 100 may selectively transmit an AHR command or an ACT command to the memory device 200 based on the over-refresh state information of each of the sub-banks SB[0] and SB[1] included in the first bank Bank[0] to access a row included in the first bank Bank[0].

For example, the memory controller 100 may selectively transmit an AHR command or an ACT command to the memory device 200 based on the over-refresh state information of the second sub-bank SB[1] to access the first row 21 included in the first sub-bank SB[0]. For example, when it is determined based on the over-refresh state information of the second sub-bank SB[1] that the number of hidden refresh operations on the second sub-bank SB[1] is less than the threshold, the memory controller 100 may transmit an AHR command including an address corresponding to the first row 21 to the memory device 200 to access the first row 21. In addition, when it is determined based on the over-refresh state information of the second sub-bank SB[1] that the number of hidden refresh operations for the second sub-bank SB[1] is greater than or equal to the threshold, the memory controller 100 may transmit an ACT command including an address corresponding to the first row 21 to the memory device 200 to access the first row 21.

The memory controller 100 may selectively transmit an AHR command or an ACT command to the memory device 200 based on the over-refresh state information of the first sub-bank SB[0] to access the second row 22 included in the second sub-bank SB[1]. For example, when it is determined based on the over-refresh state information of the first sub-bank SB[0] that the number of hidden refresh operations on the first sub-bank SB[0] is less than the threshold, the memory controller 100 may transmit an AHR command including an address corresponding to the second row 22 to the memory device 200 to access the second row 22. In addition, when it is determined based on the over-refresh state information of the first sub-bank SB[0] that the number of hidden refresh operations on the first sub-bank SB[0] is greater than or equal to the threshold, the memory controller 100 may transmit an ACT command including the address corresponding to the second row 22 to the memory device 200 to access the second row 22.

As a result, an additional hidden refresh operation may not be performed on a sub-bank in which a number of hidden refresh operations, greater than or equal to a threshold, have been performed.

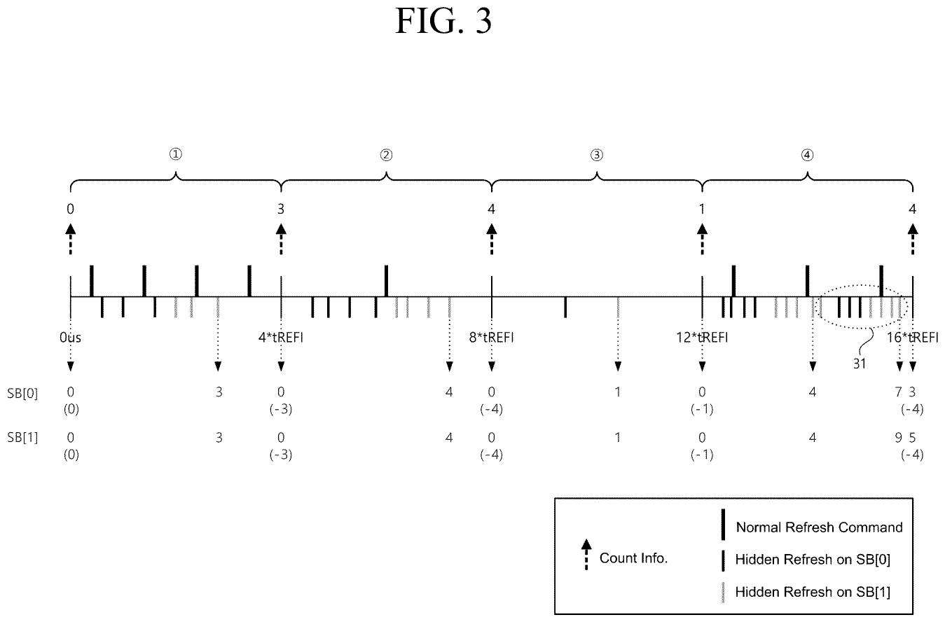

FIG. 3 is a diagram illustrating the operation of the memory system 10 according to one or more embodiments.

According to one or more embodiments, the memory device 200 may generate count information on the number of skippable normal refresh commands based on the number of hidden refresh operations performed in a corresponding bank during a unit interval. The unit interval may be a period during which the memory controller 100 inquires the count information from the memory device 200. For example, the unit interval may correspond to a predetermined number of refresh interval times tREFI, but embodiments are not limited thereto.

To this end, the memory device 200 may manage the number of hidden refresh operations performed based on AHR commands for each sub-bank. For example, the memory device 200 may increase the number of hidden refresh operations on a corresponding sub-bank each time a hidden refresh operation is performed on the sub-bank during a unit interval. In addition, the memory device 200 may decrease the number of hidden refresh operations based on count information at the end time of the unit interval. The number of hidden refresh operations may be rolled over to the next unit interval.

The memory device 200 may store the generated count information in a mode register. When a command for inquiring count information (for example, a mode register read command) is received from the memory controller 100, the memory device 200 may provide the count information stored in the mode register to the memory controller 100. Hereinafter, the mode register storing the count information is referred to as a “second mode register,” and the mode register read command for inquiring or polling the count information stored in the second mode register is referred to as a “second mode register read command.”

The memory controller 100 may inquire the memory device 200 for count information on the number of skippable normal refresh commands for each unit interval and determine the number of normal refresh commands to be transmitted to a corresponding bank in the next unit interval based on the obtained count information.

FIG. 3 is a diagram illustrating an example of normal refresh operations and hidden refresh operations performed on a bank including two sub-banks SB[0] and SB[1]. In the example of FIG. 3, each unit interval \textcircled{1}, \textcircled{2}, \textcircled{3}, or \textcircled{4} corresponds to four refresh interval times tREFI. Therefore, four normal refresh commands should be applied during each unit interval. In addition, FIG. 3 illustrates an example in which normal refresh operations are performed on two rows per bank (one row per sub-bank) for each normal refresh command. In addition, FIG. 3 illustrates an example in which the memory controller 100 uses only AHR commands to access the bank.

Referring to FIG. 3, there is no previous unit interval before unit interval \textcircled{1}, so that the number of skippable normal refresh commands for unit interval \textcircled{1} is 0. As illustrated in the drawing, four normal refresh commands are applied during unit interval \textcircled{1}.

As illustrated in the example, three hidden refresh operations may be performed on each of SB[0] and SB[1] during unit interval \textcircled{1}. The memory device 200 may increase the number of hidden refresh operations on a corresponding sub-bank each time a hidden refresh operation is performed on SB[0] or SB[1]. Therefore, the number of hidden refresh operations on each of SB[0] and SB[1] may be 3 at a time point at which the last hidden refresh operation is performed. This corresponds to three normal refresh commands, so that the memory device 200 may generate “3” as count information and store the generated count information in the second mode register.

The memory controller 100 may transmit a command for inquiring count information (for example. a second mode register read command) to the memory device 200 at the end time of unit interval \textcircled{1} to inquire the count information, and the memory device 200 may provide the count information “3” to the memory controller 100. The memory device 200 may decrease the number of hidden refresh operations on each of SB[0] and SB[1] by the count information “3.” Therefore, the number of hidden refresh operations on each of SB[0] and SB[1] may become “0” at the end time of unit interval \textcircled{1}.

The memory controller 100 may determine the number of normal refresh commands to be transmitted to a corresponding bank during the next unit interval based on the obtained count information. For example, subtracting the number of skippable normal refresh commands “3” from the number of normal refresh commands required during a unit interval “4” results in 1. Therefore, the memory controller 100 may determine “1” as the number of normal refresh commands to be transmitted to the corresponding bank during unit interval \textcircled{2}, the next unit interval. Accordingly, a single normal refresh command may be applied to a corresponding bank during unit interval \textcircled{2}.

During unit interval \textcircled{2}, four hidden refresh operations were performed on each of SB[0] and SB[1]. Therefore, the number of hidden refresh operations for each of SB[0] and SB[1] may be 4 at a time point at which the last hidden refresh operation is performed. This corresponds to four normal refresh commands. Accordingly, the count information “4” may be provided to the memory controller 100 at the end time of unit interval \textcircled{2}. In addition, the number of hidden refresh operations on each of SB[0] and SB[1] may decrease by the count information “4” and become “0.”

Subtracting the number of skippable normal refresh commands “4” from the number of normal refresh commands required during a unit interval “4” results in 0. Therefore, the memory controller 100 may determine “0” as the number of normal refresh commands to be transmitted to a corresponding bank during unit interval \textcircled{3}, the next unit interval. As can be seen in FIG. 3, normal refresh commands are not applied during unit interval \textcircled{3}.

One hidden refresh operation was performed on each of SB[0] and SB[1] during unit interval \textcircled{3}. Therefore, the number of hidden refresh operations on each of SB[0] and SB[1] may be 1 at a time point at which the last hidden refresh operation is performed. This corresponds to a single normal refresh command. Therefore, the count information “1” may be provided to the memory controller 100 at the end time of unit interval \textcircled{3}. In addition, the number of hidden refresh operations on each of SB[0] and SB[1] may decrease by the count information “1” and become “0.”

Subtracting the number of skippable normal refresh commands “1” from the number of normal refresh commands required during a unit interval “4” results in 3. Therefore, the memory controller 100 may determine “3” as the number of normal refresh commands to be transmitted to a corresponding bank during unit interval \textcircled{4}, the next unit interval. As can be seen in FIG. 3, three normal refresh commands are applied to the corresponding bank during unit interval \textcircled{4}.

According to the above-described embodiments, at least a portion of the required normal refresh operations may be replaced by hidden refresh operations. While bank access is not allowed during normal refresh operations, hidden refresh operations may be performed along with bank access. Thus, at least a portion of the normal refresh operations may be replaced with hidden refresh operations to improve the performance of the memory device 200.

Referring to FIG. 3, during unit interval \textcircled{4}, seven hidden refresh operations were performed on SB[0] and nine hidden refresh operations were performed on SB[1]. Therefore, the number of hidden refresh operations on SB[0] may be 7 and the number of hidden refresh operations for SB[1] may be 9 at a time point at which the last hidden refresh operation is performed.

This may correspond to seven normal refresh commands. However, the number of normal refresh commands required during a unit interval is 4, so that the maximum number of normal refresh commands skippable in the next unit interval is also 4. Therefore, the memory device 200 may provide the count information “4” to the memory controller 100 at the end time of unit interval \textcircled{4}. The memory device 200 may decrease the number of hidden refresh operations on each of SB[0] and SB[1] by the count information “4.” Accordingly, at the end time of unit interval \textcircled{4}, the number of hidden refresh operations on SB[0] may be 3 and the number of hidden refresh operations on SB[1] may be 5. The number of hidden refresh operations on SB[0] “3” and the number of hidden refresh operations on SB[1] “5” may each be rolled over to the next unit interval.

The maximum number of normal refresh commands skippable in a unit interval is 4, so that hidden refresh operations corresponding to reference numeral 31 are unnecessary hidden refresh operations in which the hidden refresh operations cannot replace normal refresh operations in the next unit interval. The hidden refresh operations are performed along with activation operations, which may increase power noise and introduce additional timing delays. Therefore, unnecessary hidden refresh operations should be prevented to avoid performance degradation and excess power consumption.

A description has been provided for the embodiment in which the maximum number of skippable normal refresh commands (for example, the maximum value of count information) is determined based on a single subsequent unit interval. For example, in unit interval \textcircled{4} of FIG. 3, hidden refresh operations corresponding to seven normal refresh commands were performed during unit interval \textcircled{4}. However, the number of normal refresh commands required for a single subsequent unit interval is 4. Therefore, as described above, the count information generated at the end time of unit interval \textcircled{4} is “4.” However, embodiments are not limited thereto.

According to an embodiment, the maximum value of count information may be determined based on two subsequent unit intervals. For example, in unit interval \textcircled{4} of FIG. 3, hidden refresh operations corresponding to seven normal refresh commands were performed during unit interval \textcircled{4}. In addition, the number of normal refresh commands required for two subsequent unit intervals is 8. Therefore, the count information generated at the end time of unit interval \textcircled{4} may be “7.” Four normal refresh commands required for the first subsequent unit interval of unit interval \textcircled{4} and three of the four normal refresh commands required for the second subsequent unit interval of unit interval \textcircled{4} may be skipped due to the hidden refresh operations performed during unit interval \textcircled{4}.

However, embodiments are not limited thereto, and the maximum value of count information may be determined based on three or more subsequent unit intervals.

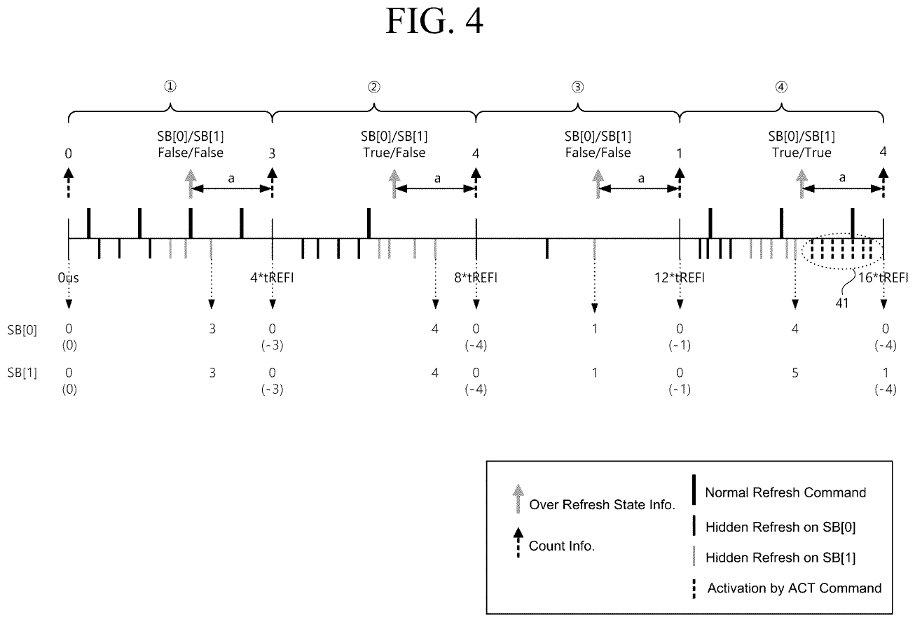

FIG. 4 is a diagram illustrating the operation of the memory system 10 according to one or more embodiments.

According to one or more embodiments, the memory controller 100 may selectively use an AHR command or an ACT command to access a row included in a bank of the memory device 200. The memory controller 100 may select either an AHR command or an ACT command based on over-refresh state information.

To this end, the memory device 200 may generate over-refresh state information for a corresponding sub-bank based on the number of hidden refresh operations managed for each sub-bank. The management of the number of hidden refresh operations performed based on AHR commands for each sub-bank by the memory device 200 may be as described above. The over-refresh state information may indicate whether the number of hidden refresh operations performed on the corresponding sub-bank during a unit interval is greater than or equal to a threshold.

The threshold may be the number of hidden refresh operations per sub-bank required to replace all normal refresh commands required to be issued to a bank during a unit interval. According to one or more embodiments, the threshold may be determined based on the number of normal refresh commands corresponding to the unit interval and the number of rows refreshed per normal refresh command. The unit interval may be a period during which the memory controller 100 inquires count information from the memory device 200. The unit interval may correspond to a predetermined number of refresh interval times tREFI, but embodiments are not limited thereto. In addition, the number of normal refresh commands corresponding to a unit interval may refer to the number of normal refresh commands required to be issued to the bank during the unit interval.

For example, when a unit interval corresponds to four refresh interval times tREFI, four normal refresh commands are required to be issued to a bank during the unit interval. Then, the number of normal refresh commands corresponding to the unit interval may be 4. When an example is provided in which a bank includes two sub-banks and the number of rows refreshed in the bank per normal refresh command is 2 (for example, one row per sub-bank), four hidden refresh operations per sub-bank are needed to replace four normal refresh commands, so that the threshold may be 4. Alternatively, when an example is provided in which a bank includes two sub-banks and the number of rows refreshed in the bank per normal refresh command is 8 (for example, four rows per sub-bank), 16 hidden refresh operations per sub-bank are needed to replace four normal refresh commands, so that the threshold may be 16.

According to one or more embodiments, the memory device 200 may transmit over-refresh state information to the memory controller 100, corresponding to a time point at which a command for inquiring over-refresh state information is received from the memory controller 100. The memory controller 100 may transmit the command for inquiring over-refresh state information to the memory device 200 a predetermined time before the end of the unit interval.

According to one or more embodiments, the memory device 200 may store the generated over-refresh state information in the first mode register. The memory device 200 may provide the over-refresh state information to the memory controller 100, corresponding to a time point at which a command for inquiring over-refresh state information (for example, a first mode register read command) is received from the memory controller 100.

According to one or more embodiments, the memory device 200 may provide the over-refresh state information prestored in the first mode register to the memory controller 100 at a time point at which the first mode register read command is received. Alternatively, according to one or more embodiments, the memory device 200 may update the first mode register with the current over-refresh state information based on the time point at which the first mode register read command is received and provide the updated over-refresh state information to the memory controller 100.

As a result, the memory controller 100 may selectively transmit an AHR command or an ACT command to the memory device 200 based on the over-refresh state information during the time between a time point at which the over-refresh state information is obtained and the end of the unit interval.

FIG. 4 is a diagram illustrating an example in which normal refresh operations and hidden refresh operations are performed on a bank including two sub-banks SB[0] and SB[1], as in the example of FIG. 3. The unit intervals \textcircled{1}, \textcircled{2}, \textcircled{3}, or \textcircled{4} and the number of rows refreshed per normal refresh command are also the same as in the example of FIG. 3. In contrast to FIG. 3, FIG. 4 illustrates that the memory device 200 may generate over-refresh state information and transmit the generated over-refresh state information to the memory controller 100. In FIG. 4, False indicates over-refresh state information when the number of hidden refresh operations on a corresponding sub-bank is less than a threshold, and True indicates over-refresh state information when the number of hidden refresh operations on a corresponding sub-bank is greater than or equal to the threshold.

Referring to FIG. 4, four normal refresh commands are applied to a bank during unit interval \textcircled{1}. In addition, three hidden refresh operations are performed on each of SB[0] and SB[1] during unit interval \textcircled{1}. At a time point at which the last hidden refresh operation is performed, the number of hidden refresh operations on each of SB[0] and SB[1] is 3. This corresponds to three normal refresh commands, so that the memory device 200 may generate “3” as count information and store the generated count information in the second mode register.

The memory controller 100 may transmit a command for inquiring count information (for example, a second mode register read command) to the memory device 200 at the end time of unit interval \textcircled{1} to inquire the count information, and the memory device 200 may provide the count information “3” to the memory controller 100. The memory device 200 may decrease the number of hidden refresh operations on each of SB[0] and SB[1] by the count information “3.” Therefore, the number of hidden refresh operations on each of SB[0] and SB[1] may be “0” at the end time of unit interval \textcircled{1}. The memory controller 100 may determine “1” as the number of normal refresh commands to be transmitted to a corresponding bank during unit interval \textcircled{2}, the next unit interval, based on the obtained count information “3.” This is as described in FIG. 3.

According to one or more embodiments, the memory device 200 may generate over-refresh state information based on the number of hidden refresh operations and store the generated over-refresh state information in the first mode register. In addition, the memory device 200 may transmit over-refresh state information to the memory controller 100, corresponding to a time point at which a command for inquiring over-refresh state information (for example, a first mode register read command) is received from the memory controller 100.

According to one or more embodiments, the memory controller 100 may transmit a command for inquiring over-refresh state information to the memory device 200 a predetermined time “a” before the end of each unit interval. As can be seen in FIG. 4, over-refresh state information may be transmitted to the memory controller 100 a predetermined time before the end of each unit interval.

In the example of FIG. 4, the number of normal refresh commands corresponding to a unit interval is 4 and the number of rows refreshed per normal refresh command is 2 (for example, one row per sub-bank), so that the threshold is 4. The number of hidden refresh operations on SB[0] is 3 and the number of hidden refresh operations on SB[1] is 2, based on the time point at which over-refresh state information is transmitted within unit interval \textcircled{1}. Both values are less than the threshold, so that the memory device 200 may transmit over-refresh state information False/False for SB[0]/SB[1] to the memory controller 100.

The memory controller 100 may selectively transmit an AHR command or an ACT command to the memory device 200 based on the over-refresh state information False/False during the time “a” between when the over-refresh state information False/False is obtained and the end of unit interval \textcircled{1}.

For example, the over-refresh state information for both SB[0] and SB[1] is False, so that the memory controller 100 may access SB[0] or SB[1] using an AHR command. As illustrated in the drawing, during the time “a” of unit interval \textcircled{1}, one AHR command is applied to access a row in SB[0] and one hidden refresh operation is performed on SB[1].

During unit interval \textcircled{2}, one normal refresh command is applied to the corresponding bank. In addition, four hidden refresh operations are performed on each of SB[0] and SB[1] during unit interval \textcircled{2}, so that the number of hidden refresh operations on each of SB[0] and SB[1] is 4 at the time point at which the last hidden refresh operation is performed. This corresponds to four normal refresh commands, and the count information “4” may be provided to the memory controller 100. Accordingly, the memory controller 100 may determine “0” as the number of normal refresh commands to be transmitted to a corresponding bank during unit interval \textcircled{3}, the next unit interval. This is as described in FIG. 3.

The number of hidden refresh operations on SB[0] is 4 and the number of hidden refresh operations on SB[1] is 2, based on the time point at which over-refresh state information is transmitted within unit interval \textcircled{2}. The number of hidden refresh operations for SB[0] has reached the threshold, so that the over-refresh state information for SB[0] is set to True. In addition, the number of hidden refresh operations for SB[1] is below the threshold, so that the over-refresh state information for SB[1] is False.

The memory controller 100 may selectively transmit an AHR command or an ACT command to the memory device 200 based on the over-refresh state information True/False during the time “a” between when the over-refresh state information True/False is obtained and the end of unit interval \textcircled{2}.

For example, the over-refresh state information for SB[0] is set to True, so that the memory controller 100 may access SB[1] using an ACT command during the time “a” of unit interval \textcircled{2}. In addition, the over-refresh state information for SB[1] is False, so that the memory controller 100 may access SB[0] using an AHR command during the time “a” of unit interval \textcircled{2}. As illustrated in the drawing, during the time “a” of unit interval \textcircled{2}, two AHR commands are applied to access rows in SB[0] and two hidden refresh operations are performed on SB[1].

As described above, the number of normal refresh commands to be transmitted during unit interval \textcircled{3}, has been determined as “0” by the memory controller 100, so that a normal refresh command is not applied to a corresponding bank during unit interval \textcircled{3}.

In addition, one hidden refresh operation is performed on each of SB[0] and SB[1] during unit interval \textcircled{3}, so that the number of hidden refresh operations on each of SB[0] and SB[1] is 1 at a time point at which the last hidden refresh operation is performed. This corresponds to a single normal refresh command, and the count information “1” may be provided to the memory controller 100. Accordingly, the memory controller 100 may determine “3” as the number of normal refresh commands to be transmitted to the corresponding bank during unit interval \textcircled{4}, the next unit interval. This is as described in FIG. 3.

The number of hidden refresh operations on each of SB[0] and SB[1] is 1 based on the time point at which over-refresh state information is transmitted within unit interval \textcircled{3}. Both values are less than the threshold, so that the over-refresh state information for both SB[0] and SB[1] is False.

The memory controller 100 may selectively transmit an AHR command or an ACT command to the memory device 200 based on the over-refresh state information False/False during the time “a” between a time point at which the over-refresh state information False/False is obtained and the end of unit interval \textcircled{3}.

For example, the over-refresh state information for both SB[0] and SB[1] is False, so that the memory controller 100 may access SB[0] or SB[1] using an AHR command during the time “a” of unit interval \textcircled{3}. In the example illustrated, an AHR command is not applied to access a row included in SB[0] or SB[1] during the time “a” of unit interval \textcircled{3}, so that an additional hidden refresh operation was not performed on SB[0] or SB[1].

During unit interval \textcircled{4}, three normal refresh commands are applied to a corresponding bank. In addition, four hidden refresh operations are performed on SB[0] and five hidden refresh operations are performed on SB[1] during unit interval \textcircled{4}, so that the numbers of hidden refresh operations on SB[0] and SB[1] are 4 and 5, respectively, at a time point at which the last hidden refresh operation is performed. This corresponds to four normal refresh commands, and the count information “4” may be provided to the memory controller 100. The memory device 200 may decrease the number of hidden refresh operations on each of SB[0] and SB[1] by the count information “4.” Therefore, the number of hidden refresh operations on SB[0] may be 0 and the number of hidden refresh operations on SB[1] may be 1 at the end time of unit interval \textcircled{4}. The number of hidden refresh operations on SB[1], which is 1, may be rolled over to the next unit interval.

The number of hidden refresh operations for SB[0] is 4 and the count for SB[1] is 5, based on the time point at which over-refresh state information is transmitted within unit interval \textcircled{4}. The numbers of hidden refresh operations on both SB[0] and SB[1] have reached the threshold, so that the over-refresh state information for both SB[0] and SB[1] is set to True.

The memory controller 100 may selectively transmit an AHR command or an ACT command to the memory device 200 based on the over-refresh state information True/True during the time “a” between a time point at which the over-refresh state information True/True is obtained and the end of unit interval \textcircled{4}.

The over-refresh state information for both SB[0] and SB[1] is True, so that the memory

controller 100 may access a row included in SB[0] or SB[1] using an ACT command during the time “a” of unit interval \textcircled{4}. An AHR command is not applied during the time “a” of unit interval \textcircled{4}, so that an additional hidden refresh operation is not performed on SB[0] or SB[1]. As illustrated at reference numeral 41, seven ACT commands are applied to access rows included in SB[0] or SB[1] during the time “a” of unit interval \textcircled{4}, and thus seven activation operations are performed while a hidden refresh operation is not performed.

In contrast FIG. 3 in which only AHR commands are used to access rows in a bank, FIG. 4 illustrates that AHR commands or ACT commands may be selectively used based on over-refresh state information. Accordingly, performance degradation and power consumption of the memory device 200 caused by unnecessary hidden refresh operations may be prevented and reduced.

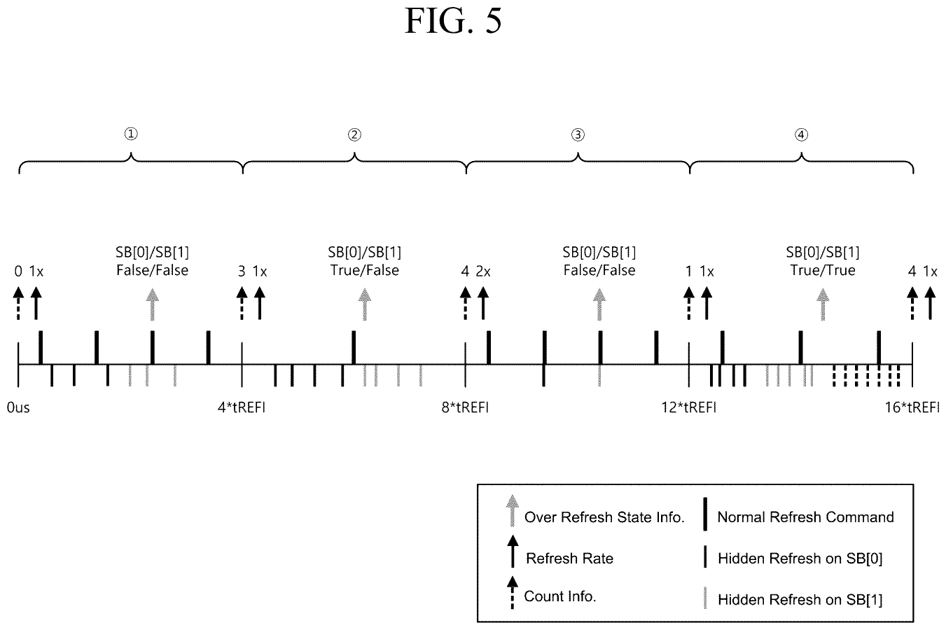

FIG. 5 is a diagram illustrating the operation of the memory system 10 according to one or more embodiments. FIG. 5 illustrates the same example as in FIG. 4, except that the refresh rate is doubled during unit interval \textcircled{3}.

According to one or more embodiments, the number of normal refresh commands required to be issued during each unit interval may be determined by reflecting a refresh rate based on temperature. Referring to FIG. 5, the refresh rate is 1× during unit intervals \textcircled{1}, \textcircled{2}, and \textcircled{4}, so that the number of normal refresh commands required to be issued during unit interval \textcircled{1}, \textcircled{2}, or \textcircled{4} may be 4. However, the refresh rate is 2× during unit interval \textcircled{3}, so that the number of normal refresh commands required to be issued during unit interval \textcircled{3} may be 8.

According to one or more embodiments, the memory controller 100 may determine the number of normal refresh commands to be transmitted during the next unit interval based on the count information obtained at the end time of a unit interval and the number of normal refresh commands required to be applied during the next unit interval, obtained at the start time of the next unit interval.

For example, the memory controller 100 may obtain count information indicating the number of skippable normal refresh commands during the next unit interval at the end time of the unit interval. When the count information is obtained, the memory controller 100 may obtain refresh rate information based on temperature from the memory device 200 through a third mode register read command (for example, a mode register read command requiring a value of a mode register such as MR4 in which refresh rate information based on temperature is stored). Accordingly, the memory controller 100 may determine the number of normal refresh commands required to be issued during the next unit interval based on the refresh rate information.

Accordingly, the memory controller 100 may determine the number of normal refresh commands to be transmitted during the next unit interval by subtracting the number of normal refresh commands indicated by the count information from the number of normal refresh commands determined based on the refresh rate information.

For example, there is no previous unit interval during unit interval \textcircled{1}, so that the number of skippable normal refresh commands during unit interval \textcircled{1}, for example, the count information, is 0. Accordingly, the memory controller 100 may transmit four normal refresh commands during unit interval \textcircled{1}.

The number of normal refresh commands required during unit interval \textcircled{2} is 4, and the count information obtained at the end time of unit interval \textcircled{1} is 3. Therefore, the memory controller 100 may determine 1(=4−3) as the number of normal refresh commands to be transmitted during unit interval \textcircled{2} and transmit a single normal refresh command during unit interval \textcircled{2}.

The number of normal refresh commands required during unit interval \textcircled{3} is 8, and the count information obtained at the end time of unit interval \textcircled{2} is 4. Therefore, the memory controller 100 may determine 4(=8−4) as the number of normal refresh commands to be transmitted during unit interval \textcircled{3} and transmit four normal refresh commands during unit interval \textcircled{3}.

The number of normal refresh commands required during unit interval \textcircled{4} is 4, and the count information obtained at the end time of unit interval \textcircled{3} is 1. Therefore, the memory controller 100 may determine 3(=4−1) as the number of normal refresh commands to be transmitted during unit interval \textcircled{4} and transmit three normal refresh commands during unit interval \textcircled{4}.

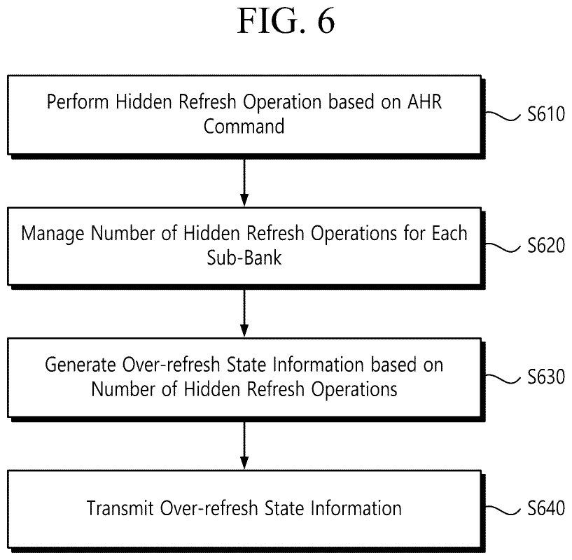

FIG. 6 is a flowchart illustrating a method of operating a memory device according to one

or more embodiments. Referring to FIG. 6, in operation S610, the memory device 200 may perform a hidden refresh operation based on an AHR command. For example, the first bank Bank[0] included in the memory device 200 may include a first sub-bank SB[0] including a first row and a second sub-bank SB[1] including a second row.

When an AHR command for accessing the first row is received from the memory controller 100, the memory device 200 may simultaneously perform an activation operation on the first row and a hidden refresh operation on the second row based on the received AHR command. When an AHR command for accessing the second row is received from the memory controller 100, the memory device 200 may simultaneously perform an activation operation on the second row and a hidden refresh operation on the first row based on the received AHR command. This may be similarly applied to each of the plurality of banks Bank[0] to Bank[n-1] included in the memory device 200.

In operation S620, the memory device 200 may manage the number of hidden refresh operations for each sub-bank.

For example, the memory device 200 may increase the number of hidden refresh operations on a corresponding sub-bank each time a hidden refresh operation is performed on the sub-bank during a unit interval. In addition, the memory device 200 may decrease the number of hidden refresh operations on the corresponding sub-bank at the end time of the unit interval based on count information. The unit interval and count information have been described in detail with reference to FIGS. 3 to 5, and detailed descriptions thereof are omitted. The number of hidden refresh operations may be rolled over to the next unit interval.

In operation S630, the memory device 200 may generate over-refresh state information for the corresponding sub-bank based on the number of hidden refresh operations.

The over-refresh state information may indicate whether the number of hidden refresh operations performed on the corresponding sub-bank is greater than or equal to a threshold. According to one or more embodiments, the memory device 200 may generate the over-refresh state information in the form of a bitmap. A bit representing the over-refresh state information may have a first value (for example, 0) when the number of hidden refresh operations is less than the threshold and a second value (for example, 1) when the number of hidden refresh operations is greater than or equal to the threshold.

The threshold may be determined based on the number of normal refresh commands corresponding to the unit interval and the number of rows refreshed per normal refresh command. The threshold has been described in detail with reference to FIG. 4, and a description thereof is omitted.

According to one or more embodiments, the memory device 200 may store the over-refresh state information in the first mode register. For example, when the memory cell array 310 of the memory device 200 includes 32 banks each including two sub-banks and the over-refresh state information is represented as 1 bit, the over-refresh state information for all 64 sub-banks is represented as 64 bits. In an example in which a single first mode register stores 8 bits, the memory device 200 may store the over-refresh state information for all sub-banks using eight first mode registers.

According to one or more embodiments, the memory device 200 may store or update the over-refresh state information in the first mode register at each expiration of a dedicated timer. In addition, the memory device 200 may store or update the over-refresh state information in the first mode register each time a first mode register read command including an update-inquire operation bit having a predetermined value is received. The update-inquire operation bit will be described immediately below.

In operation S640, the memory device 200 may transmit the over-refresh state information. For example, the memory device 200 may receive a command for inquiring over-refresh state information from the memory controller 100. Accordingly, the memory device 200 may transmit the over-refresh state information to the memory controller 100 in response to the received command for inquiring over-refresh state information. The command for inquiring over-refresh state information may include a first mode register read command or a read command.

According to one or more embodiments, the memory device 200 may receive a first mode register read command from the memory controller 100. The first mode register read command may include an update-inquire operation bit and/or a burst operation bit.

The update-inquire operation bit may determine whether to update the over-refresh state information based on the time point at which the memory device 200 receives the first mode register read command. For example, when a first mode register read command having an update-inquire operation bit set to a first value (for example, 0) is received, the memory device 200 may transmit the over-refresh state information stored in the first mode registers to the memory controller 100 without updating the stored over-refresh state information. However, when a first mode register read command having an update-inquire operation bit set to a second value (for example, 1) is received, the memory device 200 may update the first mode registers with the current over-refresh state information and transmit the updated over-refresh state information to the memory controller 100. Thus, the memory controller 100 may obtain the latest over-refresh state information using a first mode register read command including the update-inquire operation bit.

The burst operation bit may determine whether the memory device 200 performs a burst operation on the first mode registers. For example, when a first mode register read command having a burst operation bit set to a first value (for example, 0) is received, the memory device 200 may transmit the over-refresh state information stored in a single first mode register corresponding to the address provided in the first mode register read command to the memory controller 100. However, when a first mode register read command having a burst operation bit set to a second value (for example, 1) is received, the memory device 200 may transmit the over-refresh state information, stored in a plurality of first mode registers, to the memory controller 100 in a batch. For example, when the burst operation bit has the second value, the memory device 200 may transmit not only the over-refresh state information, stored in the first mode register corresponding to the address provided in the first mode register read command, but also the over-refresh state information, stored in the remaining first mode registers, to the memory controller 100. Thus, the memory controller 100 may obtain the over-refresh state information for all sub-banks included in the memory device 200 at once using a single first mode register read command including the burst operation bit.

According to one or more embodiments, each of the plurality of banks Bank[0] to Bank[n-1] included in the memory device 200 may include not only a normal data area in which user data is stored, but also a metadata area in which metadata is stored. A data I/O buffer of the memory device 200 may also include a normal data area in which user data is input and output, and a metadata area in which metadata is input and output. According to one or more embodiments, the memory device 200 may provide over-refresh state information to the memory controller 100 using metadata.

For example, the memory controller 100 may transmit a read command for inquiring over-refresh state information to the memory device 200. Accordingly, the memory device 200 may transmit the over-refresh state information of the sub-bank including a row corresponding to the received read command to the memory controller 100 through the metadata area of the data I/O buffer.

The read command for inquiring over-refresh state information may be implemented in various ways. According to one or more embodiments, the read command for inquiring over-refresh state information may be implemented by modifying a normal read command. For example, the read command for inquiring over-refresh state information may be implemented using one of the valid bits included in a normal read command as a flag bit indicating whether to return over-refresh state information.

When a read command having a flag bit set to a first value is received, the memory device 200 may perform the same operation as an operation based on a normal read command. However, when a read command having a flag bit set to a second value is received, the memory device 200 may store the over-refresh state information of the sub-bank including the row corresponding to the read command in at least a portion of the metadata area of the data I/O buffer. Accordingly, the over-refresh state information of the sub-bank containing the row corresponding to the read command may be transmitted to the memory controller 100 along with other data.

Alternatively, according to one or more embodiments, the read command for inquiring over-refresh state information may be implemented by configuring the memory device 200 to operate differently depending on a mode when a normal read command is received. For example, when a normal read command is received in a first mode, the memory device 200 may perform a general read operation. However, when a normal read command is received in a second mode, the memory device 200 may store the over-refresh state information of the sub-bank including the row corresponding to the read command in at least a portion of the metadata area of the data I/O buffer and transmit the stored over-refresh state information to the memory controller 100 along with other data.

An example has been provided in which, when the read command for inquiring over-refresh state information is received, the memory device 200 may provide the over-refresh state information of a single sub-bank including a row corresponding to the read command to the memory controller 100. However, embodiments are not limited thereto. For example, when the read command for inquiring over-refresh state information is received, the memory device 200 may provide over-refresh state information of a plurality of sub-banks grouped with a sub-bank including a row corresponding to the read command to the memory controller 100.

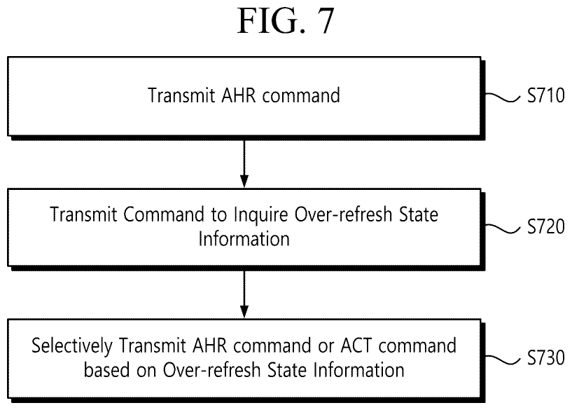

FIG. 7 is a flowchart illustrating a method of operating a memory controller according to one or more embodiments.

Referring to FIG. 7, in operation S710, the memory controller 100 may transmit an AHR command to the memory device 200. Accordingly, the memory device 200 may perform an activation operation and a hidden refresh operation based on the received AHR command. In addition, the memory device 200 may manage the number of hidden refresh operations for each sub-bank and generate over-refresh state information for each sub-bank based on the number of hidden refresh operations.

In operation S720, the memory controller 100 may transmit a command for inquiring over-refresh state information to the memory device 200. The memory device 200 may transmit the over-refresh state information to the memory controller 100 in response to the received command.

According to one or more embodiments, the memory device 200 may transmit the over-refresh state information, stored in all of a plurality of first mode registers, to the memory controller 100 at once in response to a first mode register read command having a burst operation bit set to a second value (for example, 1).

Alternatively, according to one or more embodiments, the memory device 200 may, in response to a first mode register read command having a burst operation bit set to a first value (for example, 0), transmit the over-refresh state information stored in a single first mode register corresponding to the address provided by the first mode register read command to the memory controller 100.

Alternatively, according to one or more embodiments, the memory device 200 may transmit the over-refresh state information of the sub-bank including the row corresponding to a read command to the memory controller 100.

Alternatively, according to one or more embodiments, the memory device 200 may transmit the over-refresh state information of a plurality of sub-banks grouped with a sub-bank including a row corresponding to a read command to the memory controller 100.

The memory controller 100 receiving the over-refresh state information may schedule commands to be transmitted to the memory device 200 based on the received over-refresh state information. For example, in operation S730, the memory controller 100 may selectively transmit an AHR command or an ACT command to the memory device 200 based on the over-refresh state information to access a row in a bank included in the memory device 200.

For example, the first bank Bank[0] included in the memory device 200 may include a first sub-bank including a first row and a second sub-bank including a second row. In addition, the over-refresh state information may include a first value corresponding to a state in which the number of hidden refresh operations is less than a threshold and a second value corresponding to a state in which the number of hidden refresh operations is greater than or equal to the threshold.

To access the first row, the memory controller 100 may transmit an AHR command to the memory device 200 based on the over-refresh state information of the second sub-bank being the first value and transmit an ACT command to the memory device 200 based on the over-refresh state information of the second sub-bank being the second value.

To access the second row, the memory controller 100 may transmit an AHR command to the memory device 200 based on the over-refresh state information of the first sub-bank being the first value and transmit an ACT command to the memory device 200 based on the over-refresh state information of the first sub-bank being the second value.

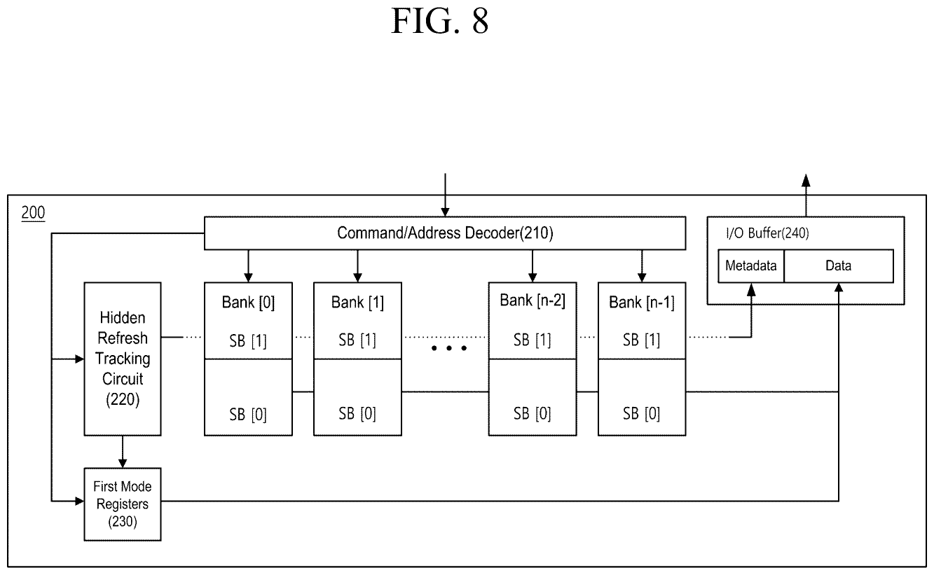

FIG. 8 is a block diagram of a memory device according to one or more embodiments. A memory device 200 of FIG. 8 may be an example of the memory device 200 of FIG. 1, but embodiments are not limited thereto. Descriptions in FIG. 8 that overlap with the above content will be omitted or simplified to avoid redundancy.

Referring to FIG. 8, the memory device 200 may include a command/address decoder 210, a plurality of banks Bank[0] to Bank[n-1], a hidden refresh tracking circuit 220, a plurality of first mode registers 230, and an I/O buffer 240.

Each of the plurality of banks Bank[0] to Bank[n-1] may include a first sub-bank SB[0] and a second sub-bank SB[1].

The command/address decoder 210 may decode command signals and address signals, received from the memory controller 100, to generate internal control signals for performing operations corresponding to command signals.

For example, when an AHR command for accessing a first row in SB[0] of Bank[0] is received, the command/address decoder 210 may generate a first control signal for activating the first row and a second control signal for refreshing a second row in SB[1] of Bank[0]. Accordingly, an activation operation on the first row and a hidden refresh operation on the second row may be performed. When an ACT command is received, the command/address decoder 210 may generate a first control signal for an activation operation. Accordingly, an activation operation on the first row may be performed.

The hidden refresh tracking circuit 220 may count and manage the number of hidden refresh operations performed based on AHR commands for each sub-bank. In addition, the hidden refresh tracking circuit 220 may generate over-refresh state information for each sub-bank based on the number of hidden refresh operations.

The hidden refresh tracking circuit 220 may store the over-refresh state information in the plurality of first mode registers 230. According to one or more embodiments, the hidden refresh tracking circuit 220 may store the over-refresh state information in the plurality of first mode registers 230 at each expiration of an internal timer. In addition, according to one or more embodiments, the hidden refresh tracking circuit 220 may store or update the over-refresh state information in the first mode registers each time a control signal corresponding to a first mode register read command is received. The first mode register read command may include an update-inquire operation bit having a predetermined value (the second value in the example described in FIG. 6).

The hidden refresh tracking circuit 220 may transmit over-refresh state information to a portion of a metadata area of the I/O buffer 240 based on a control signal corresponding to a read command for inquiring the over-refresh state information. The over-refresh state information may be over-refresh state information of the sub-bank including a target row of the read command for inquiring over-refresh state information. Alternatively, the over-refresh state information may be over-refresh state information of a plurality of sub-banks grouped with the sub-bank including the target row.

According to one or more embodiments, the hidden refresh tracking circuit 220 may update the over-refresh state information, transmitted to the metadata area of the I/O buffer 240, in the first mode register.

Although not illustrated in FIG. 8, the memory device 200 may include additional mode registers used for other purposes, besides the plurality of first mode registers 230. For example, the memory device 200 may further include at least one second mode register storing count information. In addition, the memory device 200 may further include at least one mode register storing refresh rate information based on temperature. In addition, the memory device 200 may further include a mode register configured to differently set a method of operating the memory device 200 in response to a normal read command.

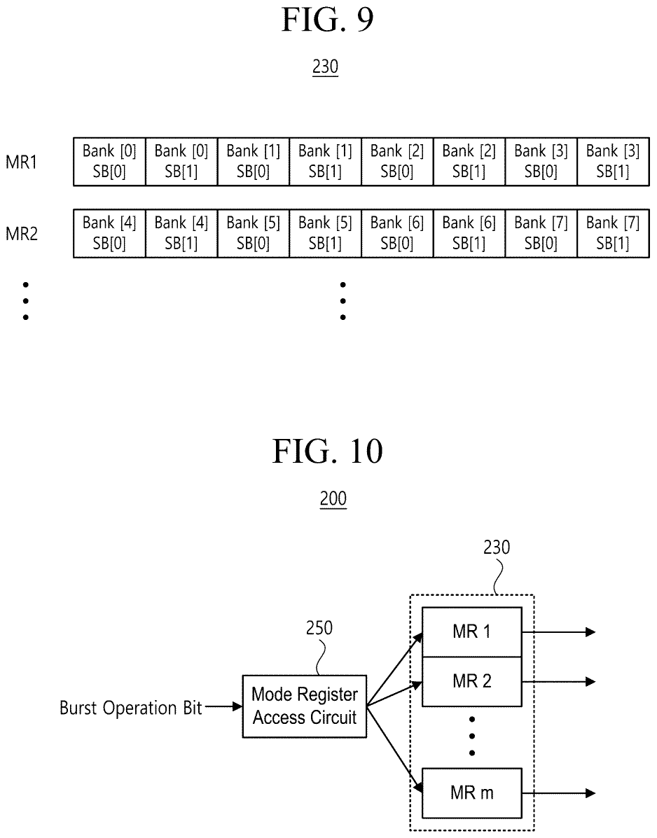

FIG. 9 is a diagram illustrating a plurality of first mode registers according to one or more embodiments. As described above, the plurality of first mode registers 230 may store over-refresh state information of a sub-banks included in the memory device 200.

According to one or more embodiments, the over-refresh state information of a single sub-bank may be represented as 1 bit. Therefore, when each of the plurality of first mode registers 230 stores 8 bits, over-refresh state information of eight sub-banks may be stored in a single first mode register.

Referring to FIG. 9, the over-refresh state information of eight sub-banks included in Bank[0] to Bank[3] may be stored in a first mode register MR1. In addition, the over-refresh state information of eight sub-banks included in Bank[4] to Bank[7] may be stored in a first mode register MR2. Similarly, the over-refresh state information of eight sub-banks may be stored in each of the remaining first mode registers in bank order. The storage order illustrated in FIG. 9 is merely exemplary, and embodiments are not limited thereto.

FIG. 10 is a diagram illustrating a burst operation according to one or more embodiments. Referring to FIG. 10, a memory device 200 may include a plurality of first mode registers 230 and a mode register access circuit 250.

The plurality of first mode registers 230 may store over-refresh state information of sub-banks included in the memory device 200.

The mode register access circuit 250 may access the over-refresh state information stored in the plurality of first mode registers 230 in a batch or access a single first mode register, based on a value of the burst operation bit included in a first mode register read command.

For example, when the burst operation bit has a first value, the mode register access circuit 250 may transmit the over-refresh state information stored in a single first mode register corresponding to the address provided through the first mode register read command to the I/O buffer 240. In addition, when the burst operation bit has a second value, the mode register access circuit 250 may transmit all the over-refresh state information stored in each of the plurality of first mode registers 230 to the I/O buffer 240.

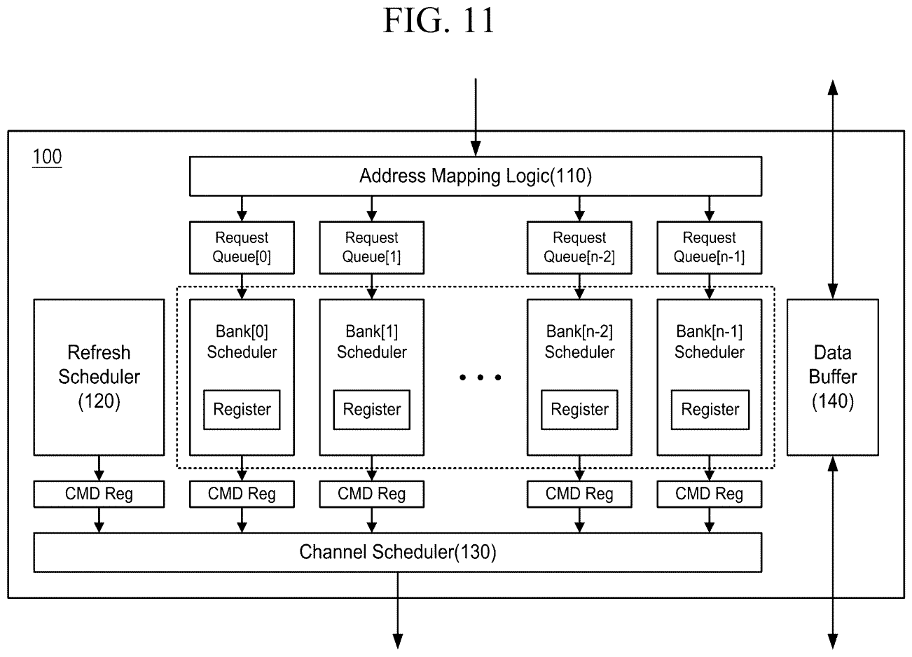

FIG. 11 is a block diagram of a memory controller according to one or more embodiments. A memory controller 100 of FIG. 11 may be an example of the memory controller 100 of FIG. 1, but embodiments are not limited thereto.

Referring to FIG. 11, the memory controller 100 may include an address mapping logic 110, a plurality of request queues Request Queue[0] to Request Queue[n-1], a refresh scheduler 120, a plurality of bank schedulers Bank[0] Scheduler to Bank[n-1] Scheduler, a plurality of command registers CMD Reg, a channel scheduler 130, and a data buffer 140.

The address mapping logic 110 may receive requests from a host and assign a bank scheduler to process each request. Requests assigned to a bank may be stored in a request queue corresponding to that bank. For example, when a first request is assigned to the Bank[0] scheduler, a first request may be stored in Request Queue[0]. Similarly, when a second request is assigned to the Bank[1] scheduler, a second request may be stored in Request Queue[1].

The plurality of bank schedulers Bank[0] Scheduler to Bank[n-1] Scheduler may correspond to the plurality of banks Bank[0] to Bank[n-1] of the memory device 200, respectively.

Each bank scheduler may schedule requests stored in a corresponding request queue and generate commands corresponding to the requests. For example, the Bank[0] scheduler may select a request to be processed first from the requests stored in Request Queue[0] and generate a command corresponding to the selected request. The generated command may be stored in a corresponding command register CMD Reg.

Each bank scheduler may include a register storing the over-refresh state information of the sub-banks included in a corresponding bank. Each bank in the memory device 200 includes two sub-banks SB[0] and SB[1], so that at least two bits may be stored in a register. Each bank scheduler may include a management circuit storing the over-refresh state information in a register and managing the stored over-refresh state information.

In addition, each bank scheduler may selectively generate an AHR command or an ACT command. To this end, each bank scheduler may include a scheduler circuit that selectively generates an AHR command or an ACT command based on the over-refresh state information stored in the corresponding register.

The refresh scheduler 120 may generate normal refresh commands. The refresh scheduler 120 may determine the number of normal refresh commands to be transmitted during the next unit interval. To this end, the refresh scheduler 120 may generate a second mode register read command to inquire about count information for each unit interval.

In addition, the refresh scheduler 120 may generate a first mode register read command to inquire over-refresh state information. According to one or more embodiments, the refresh scheduler 120 may periodically generate a first mode register read command at a time point preceding the end of a unit interval by a predetermined time.

In addition, the refresh scheduler 120 may generate a mode register read command to inquire about refresh rate information.

Commands generated by the refresh scheduler 120 may be stored in a corresponding command register CMD Reg.

The refresh scheduler 120 may initialize values of the registers storing over-refresh state information included in each bank scheduler for each unit interval.

The channel scheduler 130 may schedule various commands stored in the plurality of command registers CMD Reg and transmit the scheduled command to the memory device 200.

The data buffer 140 may temporarily store various types of data to be transmitted to or received from the host, as well as various types of data to be transmitted to or received from the memory device 200. The data received from the memory device 200 may include over-refresh state information.

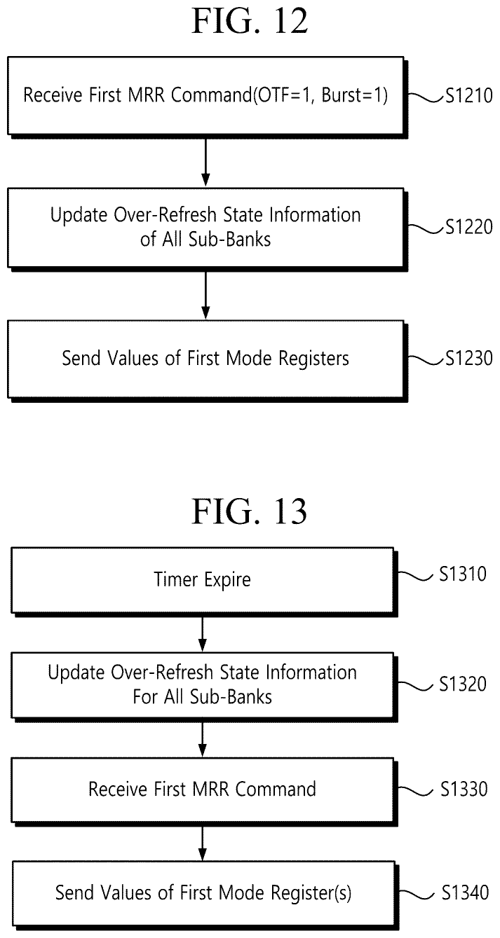

FIG. 12 is a flowchart illustrating the operation of a memory device according to one or more embodiments. Referring to FIG. 12, in operation S1210, the memory device 200 may receive a first mode register read command from the memory controller 100. The first mode register read command may include an update-inquire operation bit OTF and a burst operation bit Burst. OTF=1 and Burst=1 indicate that both an update-inquire operation and a burst operation are enabled.

Therefore, in operation S1220, the memory device 200 may update current over-refresh state information of all sub-banks in the plurality of first mode registers 230. In operation S1230, the memory device 200 may transmit values of all the updated plurality of first mode registers 230 to the memory controller 100.

FIG. 13 is a flowchart illustrating the operation of a memory device according to one or more embodiments.

Referring to FIG. 13, in operation S1310, an internal timer of the memory device 200 for updating over-refresh state information may expire.

In operation S1320, the memory device 200 may update current over-refresh state information of all sub-banks in the plurality of first mode registers 230.

In operation S1330, the memory device 200 may receive a first mode register read command from the memory controller 100.

In operation S1340, the memory device 200 may transmit the values of the first mode registers to the memory controller 100 based on the values of the update-inquire operation bit OTF and the burst operation bit Burst included in the first mode register read command.

For example, when both the update-inquire operation bit OTF and the burst operation bit Burst have enable values, the flow proceeds to operation S1340 in which the memory device 200 may update current over-refresh state information of all sub-banks in the plurality of first mode registers 230 and transmit the values of all the updated plurality of first mode registers 230 to the memory controller 100.

When both the update-inquire operation bit OTF and the burst operation bit Burst have disable values, the flow proceeds to operation S1340 in which the memory device 200 may transmit over-refresh state information, stored in a single first mode register corresponding to an address provided by the first mode register read command, to the memory controller 100 without updating current over-refresh state information.

When the update-inquire operation bit OTF has an enable value and the burst operation bit Burst has a disable value, the flow proceeds to operation S1340 in which the memory device 200 may update values of a single first mode register corresponding to an address provided by the first mode register read command having current over-refresh state information and transmit the over-refresh state information stored in the updated single first mode register to the memory controller 100.

When the update-inquire operation bit OTF has a disable value and the burst operation bit Burst has an enable value, the flow proceeds to operation S1340 in which the memory device 200 may transmit values of all the plurality of first mode registers 230 to the memory controller 100 without updating the current over-refresh state information.

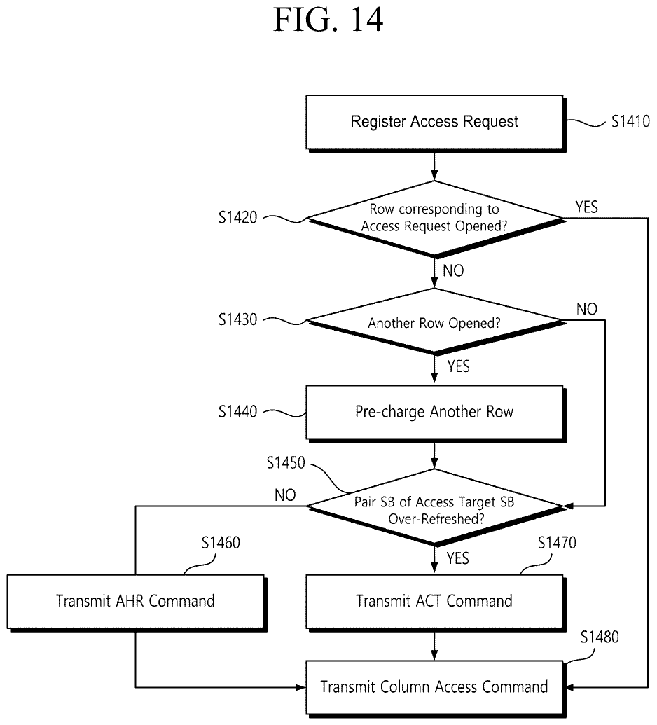

FIG. 14 is a flowchart illustrating the operation of a bank scheduler according to one or more embodiments. The bank scheduler of FIG. 14 may correspond to one of the plurality of bank schedulers Bank[0] Scheduler to Bank[n-1] Scheduler of FIG. 11.

Referring to FIG. 14, in operation S1410, an access request may be registered with a bank scheduler. In operation S1420, the bank scheduler may check whether a row corresponding to the access request is in an open (or activated) state. When the row corresponding to the access request is in an open state, the bank scheduler may perform operation S1480. In operation S1480, the bank scheduler may transmit a column access command.

When the row corresponding to the access request is not in an open state, the flow proceeds to operation S1430 in which the bank scheduler may check whether another row, different from the row corresponding to the access request, is in an open state. When the other row is in an open state, the bank scheduler may perform operation S1440. In operation S1440, the bank scheduler may precharge the other row. For example, the bank scheduler may transmit a precharge command to precharge the other row.

In operation S1450, the bank scheduler may check whether a paired sub-bank of an access target sub-bank is in an over-refreshed state. The access target sub-bank refers to one sub-bank including a row corresponding to the access request, and the pair sub-bank refers to another sub-bank included in the same bank as the access target sub-bank. For example, when a bank includes a first sub-bank and a second sub-bank and the access target sub-bank is the first sub-bank, the pair sub-bank refers to the second sub-bank. The bank scheduler may determine whether the pair sub-bank is in an over-refreshed state, based on the over-refresh state information of the pair sub-bank stored in a register.

When the pair sub-bank is in an over-refreshed state, the bank scheduler may transmit an ACT command for the row corresponding to the access request. In operation S1480, the bank scheduler may transmit a column access command.

When the pair sub-bank is not in an over-refreshed state, the bank scheduler may transmit an AHR command for the row corresponding to the access request. In operation S1480, the bank scheduler may transmit a column access command.

When the other row is not in an open state in operation S1430, the bank scheduler may perform operation S1450. This is because, when the other row is not in an open state, the other row is already in a precharged state, eliminating the need to perform operation S1440.

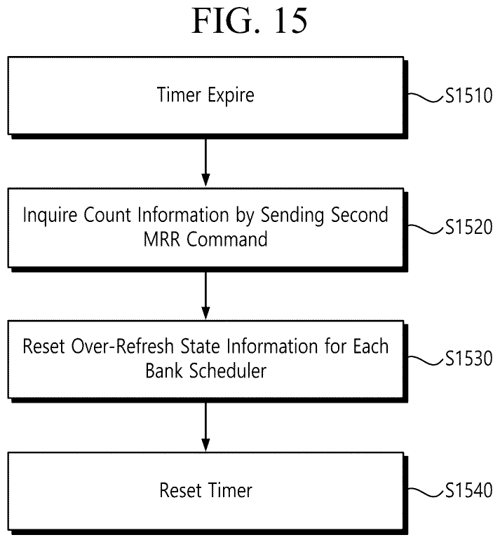

FIG. 15 is a flowchart illustrating a count information inquiry operation of a refresh scheduler according to one or more embodiments. Count information refers to information on the number of skippable normal refresh commands described above. As described in FIG. 3, the count information may be inquired for each unit interval.

The refresh scheduler of FIG. 15 may correspond to the refresh scheduler 120 of FIG. 11. In addition, each bank scheduler described in FIG. 15 refers to each of the plurality of bank schedulers Bank[0] Scheduler to Bank[n-1] Scheduler in FIG. 11.

Referring to FIG. 15, in operation S1510, a dedicated timer of the refresh scheduler 120 for inquiring count information may expire. For example, a time point at which the dedicated timer expires may be the end of the unit interval described above.

In operation S1520, the refresh scheduler 120 may transmit a second mode register read command to the memory device 200 to inquire count information. In operation S1530, the refresh scheduler 120 may reset the over-refresh state information stored in the registers of each bank scheduler. The refresh scheduler 120 may determine the number of skippable normal refresh commands during the next interval based on the obtained count information.

In operation S1540, the refresh scheduler 120 may reset the dedicated timer based on an inquiry period (or polling period) of the count information.

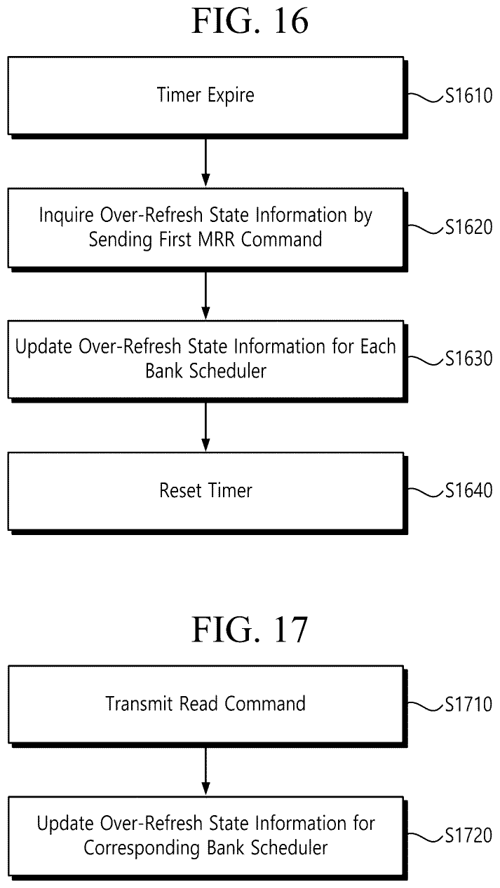

FIG. 16 is a flowchart illustrating the over-refresh state information inquiry operation of a refresh scheduler according to one or more embodiments. The refresh scheduler of FIG. 16 may correspond to the refresh scheduler 120 of FIG. 11. In addition, each bank scheduler of FIG. 16 refers to each of the plurality of bank schedulers Bank[0] Scheduler to Bank[n-1] Scheduler of FIG. 11.

Referring to FIG. 16, in operation S1610, a dedicated timer of the refresh scheduler 120 inquiring over-refresh state information may expire. A time point at which the dedicated timer expires may precede the end of a unit interval by a predetermined time.

In operation S1620, the refresh scheduler 120 may transmit a first mode register read command to the memory device 200 to inquire over-refresh state information. In operation S1630, the refresh scheduler 120 may update the values of the registers of each bank scheduler with the over-refresh state information obtained from the inquiry.

In operation S1640, the refresh scheduler 120 may reset the dedicated timer based on an inquiry period (or polling period) of the over-refresh state information.

FIG. 17 is a flowchart illustrating a method of operating a bank scheduler according to one or more embodiments. The bank scheduler of FIG. 17 refers to one of the plurality of bank schedulers Bank[0] Scheduler to Bank[n-1] Scheduler of FIG. 11.

Referring to FIG. 17, in operation S1710, the bank scheduler may transmit a read command for inquiring over-refresh state information to the memory device 200.

Accordingly, the memory device 200 may return over-refresh state information of a sub-bank including a row corresponding to the read command, or over-refresh state information of a plurality of sub-banks grouped with the sub-bank including the row corresponding to the read command, to the memory controller 100. The over-refresh state information may be included in metadata transmitted from the memory device 200 in response to the read command.

In operation S1720, the bank scheduler may update a value of a corresponding register with the returned over-refresh state information.

Examples have been mainly described in which a hidden refresh operation is performed on a single row in response to a single AHR command. However, embodiments are not limited thereto. According to one or more embodiments, hidden refresh operations on two or more rows may be performed in response to a single AHR command. Even in this case, the above-described embodiments may be applied.

Various examples have been described in which hidden refresh operations are performed based on AHR commands. However, embodiments are not limited thereto. As described in FIG. 1, a hidden refresh operation may be a refresh operation performed along with another operation based on a predetermined command other than a normal refresh command.

In one or more embodiments, a read-refresh command may be defined to simultaneously perform a read operation and a refresh operation. The memory device 200 may simultaneously perform a read operation on a row in one sub-bank (for example, SB[0]) among the sub-banks SB[0] and SB[1] included in a bank and a refresh operation on a row in another sub-bank (for example, SB[1]), based on the read-refresh command.

Alternatively, a write-refresh command may be defined to simultaneously perform a write operation and a refresh operation. The memory device 200 may simultaneously perform a write operation on a row in one sub-bank (for example, SB[0]) among the sub-banks SB[0] and SB[1] included in a bank and a refresh operation on a row in another sub-bank (for example, SB[1]), based on the write-refresh command.

Alternatively, a precharge-refresh command may be defined to simultaneously perform a precharge operation and a refresh operation. The memory device 200 may perform a precharge operation on a row in one sub-bank (for example, SB[0]) among the sub-banks SB[0] and SB[1] included in a bank and a refresh operation on a row in another sub-bank (for example, SB[1]), based on the precharge-refresh command.

Alternatively, a refresh-refresh command may be defined to simultaneously perform a refresh operation and a refresh operation. The memory device 200 may simultaneously perform a refresh operation on a row in one sub-bank (for example, SB[0]) among the sub-banks SB[0] and SB[1] included in a bank and a refresh operation on a row in another sub-bank (for example, SB[1]), based on the refresh-refresh command.

In the above examples, the refresh operations performed based on the read-refresh command, the write-refresh command, the precharge-refresh command, and the refresh-refresh command may also be the above-described hidden refresh operations.

Therefore, according to one or more embodiments, the memory device 200 may manage the number of hidden refresh operations performed based on a predetermined command for each sub-bank and generate over-refresh state information for each sub-bank based on the number of hidden refresh operations. The predetermined command may include at least one of an AHR command, a read-refresh command, a write-refresh command, a precharge-refresh command, and a refresh-refresh command.

The over-refresh state information generated in such a manner may be provided to the memory controller 100 in response to a command for inquiring over-refresh state information.

The memory controller 100 may selectively transmit the predetermined command or a single command to the memory device 200 based on the over-refresh state information. The single command may correspond to the predetermined command and include an activate command, a read command, a write command, or a precharge command.

For example, referring to FIG. 2, the memory controller 100 may selectively transmit a read-refresh command or a read command to the memory device 200 based on the over-refresh state information of each of the sub-banks SB[0] and SB[1] to perform a read operation on a row included in the first bank Bank[0].

Alternatively, the memory controller 100 may selectively transmit a write-refresh command or a write command to the memory device 200 based on the over-refresh state information of each of the sub-banks SB[0] and SB[1] to perform a write operation on a row included in the first bank Bank[0].

Alternatively, the memory controller 100 may selectively transmit a precharge-refresh command or a precharge command to the memory device 200 based on the over-refresh state information of each of the sub-banks SB[0] and SB[1] to perform a precharge operation on a row included in the first bank Bank[0].

According to the above-described embodiments, unnecessary hidden refresh operations may be prevented. As a result, the performance of a memory device may be improved and the power consumption of the memory device may be reduced.

As set forth above, according to embodiments, unnecessary hidden refresh operations may be prevented. As a result, the performance of a memory device may be improved and the power consumption of the memory device may be reduced.

While various embodiments have been shown and described above, it will be apparent to those skilled in the art that modifications and variations could be made without departing from the scope of the present inventive concept as defined by the appended claims.

What is claimed is:

1. A memory system comprising:
a memory device comprising a plurality of banks, each comprising a plurality of sub-banks; and
a memory controller configured to access a row included in the plurality of banks using an activate-refresh command or an activate command,
wherein:
the memory device is configured to manage a number of hidden refresh operations, performed based on the activate-refresh command, for each sub-bank and generate over-refresh state information based on the number of hidden refresh operations for each sub-bank; and
the memory controller is configured to selectively transmit the activate-refresh command or the activate command to the memory device based on the over-refresh state information.

2. The memory system of claim 1, wherein:
a first bank, among the plurality of banks, comprises a first sub-bank comprising a first row and a second sub-bank comprising a second row; and
the memory device is configured to:
perform an activation operation on the first row and a hidden refresh operation on the second row based on the activate-refresh command for accessing the first row; and
perform the activation operation on the first row without performing the hidden refresh operation, based on the activate command for accessing the first row.

3. The memory system of claim 2, wherein:
the over-refresh state information comprises a first value corresponding to a state in which the number of hidden refresh operations is less than a threshold and a second value corresponding to a state in which the number of hidden refresh operations is greater than or equal to the threshold; and
the memory controller is configured to:
transmit the activate-refresh command to access the first row based on the over-refresh state information of the second sub-bank corresponds to the first value; and
transmit the activate command to access the first row based on the over-refresh state information of the second sub-bank corresponds to the second value.

4. The memory system of claim 1, wherein:
the over-refresh state information indicates whether the number of hidden refresh operations performed on a corresponding sub-bank is greater than or equal to a threshold; and
the memory device is configured to:
increase the number of hidden refresh operations on the corresponding sub-bank each time the hidden refresh operation is performed on the corresponding sub-bank during a unit interval; and
transmit the over-refresh state information corresponding to a time point, at which a first command for inquiring the over-refresh state information is received from the memory controller, to the memory controller.

5. The memory system of claim 4, wherein:
the unit interval corresponds to a predetermined number of refresh interval times; and
the threshold is determined based on a number of normal refresh commands corresponding to the unit interval and a number of rows refreshed per normal refresh command.

6. The memory system of claim 4, wherein:
the memory device is configured to generate count information on a number of skippable normal refresh commands based on the number of hidden refresh operations performed during the unit interval; and
the memory controller is configured to:
transmit a second command for inquiring the count information to the memory device at an end of the unit interval; and
determine a number of normal refresh commands to be transmitted during a next unit interval based on the count information received from the memory device in response to the second command.

7. The memory system of claim 6, wherein:
the number of hidden refresh operations is reduced based on the count information at the end of the unit interval and a reduced value is rolled over to the next unit interval.

8. The memory system of claim 6, wherein:
the memory controller is configured to transmit the first command to the memory device at a predetermined time before the end of the unit interval.

9. The memory system of claim 4, wherein:
the memory device comprises a plurality of first mode registers configured to store the over-refresh state information of the plurality of sub-banks included in the plurality of banks; and
the first command comprises a mode register read command for inquiring information stored in the plurality of first mode registers.

10. The memory system of claim 9, wherein:
the mode register read command comprises an update-inquire operation bit; and
the memory device is configured to:
transmit the over-refresh state information stored in the plurality of first mode registers to the memory controller when the update-inquire operation bit has a first value; and
update the plurality of first mode registers with current over-refresh state information and transmit an updated over-refresh state information to the memory controller when the update-inquire operation bit has a second value.

11. The memory system of claim 9, wherein:
the mode register read command comprises a burst operation bit; and
the memory device is configured to:
transmit the over-refresh state information stored in a first mode register corresponding to an address provided through the mode register read command, among the plurality of first mode registers, to the memory controller when the burst operation bit has a first value; and
transmit the over-refresh state information stored in the plurality of first mode registers to the memory controller in a batch when the burst operation bit has a second value.

12. The memory system of claim 4, wherein:
the first command comprises a read command; and
the memory device comprises a data I/O buffer comprising a normal data region and a metadata region, and is configured to transmit the over-refresh state information of a sub-bank comprising a row corresponding to the read command to the memory controller through the metadata region of the data I/O buffer.

13. The memory system of claim 1, wherein:
each of the plurality of banks comprises a first sub-bank and a second sub-bank; and
the first sub-bank and the second sub-bank are respectively connected to corresponding row decoders and share a column decoder.

14. A memory device comprising:
a plurality of banks, each comprising a plurality of sub-banks;
a control logic circuit configured to activate a row included in the plurality of banks based on an activate-refresh command or an activate command; and
a hidden refresh tracking circuit configured to manage a number of hidden refresh operations, performed based on the activate-refresh command, for each sub-bank and generate over-refresh state information, indicating whether the number of hidden refresh operations is greater than or equal to a threshold, for each sub-bank.

15. The memory device of claim 14, wherein:
the hidden refresh tracking circuit is configured to:
increase the number of hidden refresh operations on a corresponding sub-bank each time a hidden refresh operation is performed on the corresponding sub-bank during a unit interval;
generate count information on a number of skippable normal refresh commands based on the number of hidden refresh operations performed during the unit interval; and
reduce the number of hidden refresh operations on the corresponding sub-bank based on the count information at an end of the unit interval; and
the unit interval is a period during which a command for inquiring the count information is received by the memory device.

16. The memory device of claim 14, comprising:
a plurality of first mode registers configured to store the over-refresh state information of the plurality of sub-banks included in the plurality of banks,
wherein:
the hidden refresh tracking circuit is configured to update the over-refresh state information in the plurality of first mode registers based on a mode register read command for inquiring information stored in the plurality of first mode registers or an expiration signal from an internal timer.

17. The memory device of claim 16, wherein:
the mode register read command comprises an update-inquire operation bit; and
the hidden refresh tracking circuit is configured to update the plurality of first mode registers to store current over-refresh state information when the update-inquire operation bit has an enable value.

18. The memory device of claim 16, wherein:
the mode register read command comprises a burst operation bit;
the over-refresh state information stored in one of the plurality of first mode registers is transmitted to a data input/output (I/O) buffer when the burst operation bit has a disable value; and
the over-refresh state information stored in the plurality of first mode registers is transmitted to the data I/O buffer in a batch when the burst operation bit has an enable value.

19. The memory device of claim 14, comprising:
a data I/O buffer comprising a normal data area and a metadata area,
wherein:
the hidden refresh tracking circuit is configured to transmit the over-refresh state information of a sub-bank comprising a row corresponding to a read command to the metadata area of the data I/O buffer.

20. A memory controller controlling an operation of a memory device, the memory controller comprising:
a plurality of bank schedulers, respectively corresponding to a plurality of banks included in the memory device,
wherein:
each of the plurality of bank schedulers is configured to schedule selective transmission of an activate-refresh command or an activate command to access a row included in a corresponding bank based on over-refresh state information of each of a plurality of sub-banks included in the corresponding bank; and
the over-refresh state information indicates whether a number of hidden refresh operations performed on a corresponding sub-bank based on the activate-refresh command is greater than or equal to a threshold and is received from the memory device.
